(19) United States
(12) Patent Application Publication
(10) Pub. No.: US 2009/0255573 A1
(43) Pub. Date: Oct. 15, 2009

(54) Photovoltaic heat-weldable thermoplastic roofing membrane

(75) Inventor: Thomas J. Taylor, Valley Cottage, NY (US)

Correspondence Address: BAKER & MCKENZIE LLP;PATENT DEPARTMENT, 2001 ROSS AVENUE, SUITE 2300, DALLAS, TX, 75201, US

(73) Assignee: BUILDING MATERIALS INVESTMENT CORPORATION, Wilmington, DE (US)

(21) Appl. No.: 12/422,130

(22) Filed: Apr. 10, 2009

Related U.S. Application Data
(60) Provisional application No. 61/044,134, filed on Apr. 11, 2008.

(51) Int. Cl. H01L 31/048; C09J 5/00

(52) U.S. Cl. 136/251; 156/325; 156/306.6

(57) ABSTRACT

Disclosed herein is the fusing of photovoltaic modules or cells to a heat-weldable thermoplastic roofing membrane, and related methods of manufacturing of the same. The resulting membrane may be used as the back sheet for sealing the back surface of photovoltaic cells/modules. In one embodiment, such a photovoltaic roofing structure may comprise a photovoltaic module with an active layer and electrodes, a transparent superstrate, and a thermoplastic olefin membrane. The transparent superstrate may be positioned on top of the photovoltaic module. Also included may be an underlying membrane comprising heat-weldable thermoplastic material positioned beneath the photovoltaic module. In addition, a frame comprised of the same heat-weldable thermoplastic material as the underlying membrane may be located on a perimeter of the superstrate and the photovoltaic module. The frame is then heat-welded to the underlying membrane around the perimeter of the photovoltaic module. Also disclosed herein are related methods of manufacturing such a photovoltaic roofing structure.

### CROSS REFERENCE TO RELATED APPLICATIONS

This patent application relates and claims priority to provisional patent application 61/044,134, filed Apr. 11, 2008, which is herein incorporated by reference for all purposes.

### TECHNICAL FIELD

This invention relates generally to photovoltaic roofing products, and more particularly to the use of a heat-weldable thermoplastic roofing membrane as the backsheet for photovoltaic (PV) modules.

### BACKGROUND

Solar energy has received increasing attention as a renewable, non-polluting energy source to produce electricity as an alternative to other non-renewable energy resources, such as coal or oil, which generate pollution. Given the increase in the price of non-renewable resources such as oil, it has become even more advantageous for companies and individuals to look to solar energy as a cost saving alternative.

In general, photovoltaic power generation systems involve photovoltaic power generation panels with solar cells converting solar energy into electric power. Photovoltaic power generation systems also typically include a connection box receiving direct current (DC) from a plurality of electrically interconnected photovoltaic panels, as well as a power conditioner converting the DC electricity supplied from the connection box into an alternating current (AC) power. The power conditioner also controls the frequency, voltage, current, phase, and output quality of the power generated by the photovoltaic panels.

Optoelectronic devices comprising the photovoltaic panels can convert radiant energy into electrical energy or vice versa. These devices generally include an active layer sandwiched between two electrodes, sometimes referred to as the front and back electrodes, at least one of which is typically transparent. The active layer typically includes one or more semiconductor materials. In a light-emitting device (e.g., a light-emitting diode), a voltage applied between the two electrodes causes a current to flow through the active layer. The current causes the active layer to emit light. In a photovoltaic device, e.g., a solar cell, the active layer absorbs energy from light and converts this energy to electrical energy exhibited as a voltage and/or current between the two electrodes.

Most conventional solar cells rely on silicon-based semiconductors. In a typical silicon-based solar cell, a layer of n-type silicon (sometimes referred to as the emitter layer) is deposited on a layer of p-type silicon. Radiation absorbed at the junction between the p-type and n-type layers generates electrons and holes. The electrons are collected by an electrode in contact with the n-type layer and the holes are collected by an electrode in contact with the p-type layer. Since light must reach the junction, at least one of the electrodes should be at least partially transparent. Many current solar cell designs use a transparent conductive oxide (TCO) such as indium tin oxide (ITO) as a transparent electrode.

Photovoltaic systems can be free-standing installations, for example, with panels installed on top of ground-based racks. Such installations are typically on underutilized or low value land (for example, semi arid areas etc). They have a disadvantage due to their distance from areas of electricity consumption, and require power transmission infrastructure investment. Alternatively, photovoltaic systems can be installed on the outer body of a structure. More specifically, photovoltaic panels may be installed on the roof, or even the wall(s) of a structure or building. In addition, there are various known techniques for installing photovoltaic power generation panels on such structures. A popular technique attaches the panels via a “racks” directly fixed to an outer roof or wall of a structure. These racks are typically designed to hold the photovoltaic panels along their edges, essentially clamping the panels together while holding them with respect to the structure. FIG. 1, discussed in detail below, illustrates such a conventional system.

Large scale arrays of such solar cells can potentially replace conventional electrical generating plants that rely on burning fossil fuels. However, in order for solar cells to provide a cost-effective alternative to conventional electric power generation, the cost per watt generated must be competitive with current electric grid rates. One challenge facing the industry is the specific type of photovoltaic cells employed. Rigid crystalline silicon solar cells have been traditionally used in roofing applications, although roofing systems employing thin-film photovoltaic cells have gained popularity. To protect the solar cells, the light incident side of the cell is covered by a transparent covering material. Accordingly, a glass sheet is typically used to form the top or light incident surface of the solar cell. An alternative method of providing a protective cover over the top of a cell is to seal the top of the cell with a material comprising a transparent thermoplastic film. However, a key reason why a glass plate is used at the outermost surface side is that the solar cell module is made to excel in weatherability and scratch resistance so that the photoelectric conversion efficiency of the cell is not reduced due to a reduction in the light transmittance of the surface-covering material when the surface-covering material is deteriorated. Particularly in view of mechanically protecting the solar cell in the solar cell module, it can be said that a glass plate is one of the most appropriate materials to be used as the surface-covering material.

The non-light incident or backside of a solar cell does not require a transparent covering, but instead is typically covered by a material that is a barrier to moisture ingress. Photovoltaic cells are readily degraded by moisture, and thus barrier materials are selected that have particularly low moisture diffusion rates. More specifically, fluoropolymer films, such as polyvinyl fluoride, are typically used. An example of such a polyvinyl fluoride film found to be suitable by the photovoltaic industry is sold as Tedlar® by DuPont.

Photovoltaic cells that are produced using glass as the top or light incident layer are normally surrounded by a metal frame. Such a frame enables the solar cell to be mounted in a rack-type assembly. This is especially advantageous for solar power generation systems that are stand-alone, such as in a field or some other open space. However, there is a need for solar cells to be better incorporated into the external surface of a building envelope. Solar cells that employ a clear plastic film for the top surface are somewhat better suited for these so-called building integrated systems due to their thin and flexible nature, but further advancement would enhance integration.

Accordingly, there is a need for a photovoltaic system specifically adapted to accommodate the use of relatively larger rigid photovoltaic cells. It would further be desirable to have a system using rigid photovoltaic cells, which would be durable and whose handling and installation would be further facilitated. Advancement of photovoltaic systems using flexible solar cells is also desirable. Such photovoltaic systems could be employed in numerous applications, but would be particularly advantageous in roofing applications.

### BRIEF SUMMARY

This disclosure pertains to the fusing of photovoltaic modules or cells to a heat-weldable thermoplastic roofing membrane, and related methods of manufacturing and installation for such a roofing membrane product. The resulting membrane may be used as the back sheet for sealing the back surface of photovoltaic cells/modules. According to one aspect, this disclosure provides the attachment of a photovoltaic module to a roof membrane directly. According to another aspect, however, a fluorinated vinyl polymer film, such as polyvinyl fluoride (PVF) or polyvinylidene fluoride (PVDF), is laminated to the top surface of the heat-weldable thermoplastic roofing membrane prior to the affixing of the solar modules. Constructing a photovoltaic module on a heat-weldable thermoplastic underlying membrane in accordance with the principles disclosed herein provides several advantages over conventional construction techniques and materials, and these advantages are discussed in greater detail below. As used herein, the term “heat-weld” and its variants refers to the heat-based or molten fusing of like or substantially similar materials to bond the materials together in a manner more permanent than merely adhering the materials together. The process would involve the heating of the materials at the point of the bond to a molten or partially liquefied state such that the materials fuse to one another at the heated bond point(s) with or without the use of a third material, such as a flux material, used to promote the fusing.

In one aspect, a photovoltaic roofing membrane is provided, which in an exemplary embodiment may comprise a photovoltaic module with an active layer and electrodes and a transparent superstrate. The transparent superstrate may be positioned on top of the photovoltaic module. Also included may be an underlying membrane comprising heat-weldable thermoplastic material positioned beneath the photovoltaic module. In addition, a frame comprised of the same heat-weldable thermoplastic material as the underlying membrane may be located on a perimeter of the superstrate and the photovoltaic module. The frame is then heat-welded to the underlying membrane around the perimeter of the photovoltaic module.

In another aspect, a method for manufacturing a photovoltaic roofing membrane is provided. In one embodiment, such a method may comprise constructing a photovoltaic module by providing an active layer and electrodes, and positioning a transparent superstrate on top of the photovoltaic module. The method may further include positioning an underlying membrane comprising heat-weldable thermoplastic material beneath the photovoltaic module. Additionally, the method may include providing a frame comprised of the same heat-weldable thermoplastic material as the underlying membrane on a perimeter of the superstrate and the photovoltaic module. Then, the method could comprise heat-welding the frame to the underlying membrane around the perimeter of the photovoltaic module.

### BRIEF DESCRIPTION OF THE DRAWINGS

FIG. 1 illustrates a partial side cross-sectional view of a conventional photovoltaic module;

FIG. 2 illustrates a partial side cross-sectional view of a photovoltaic module constructed in accordance with the present disclosure; and

FIG. 3 illustrates a partial side cross-sectional view of another embodiment of a photovoltaic module constructed in accordance with the present disclosure.

### DETAILED DESCRIPTION

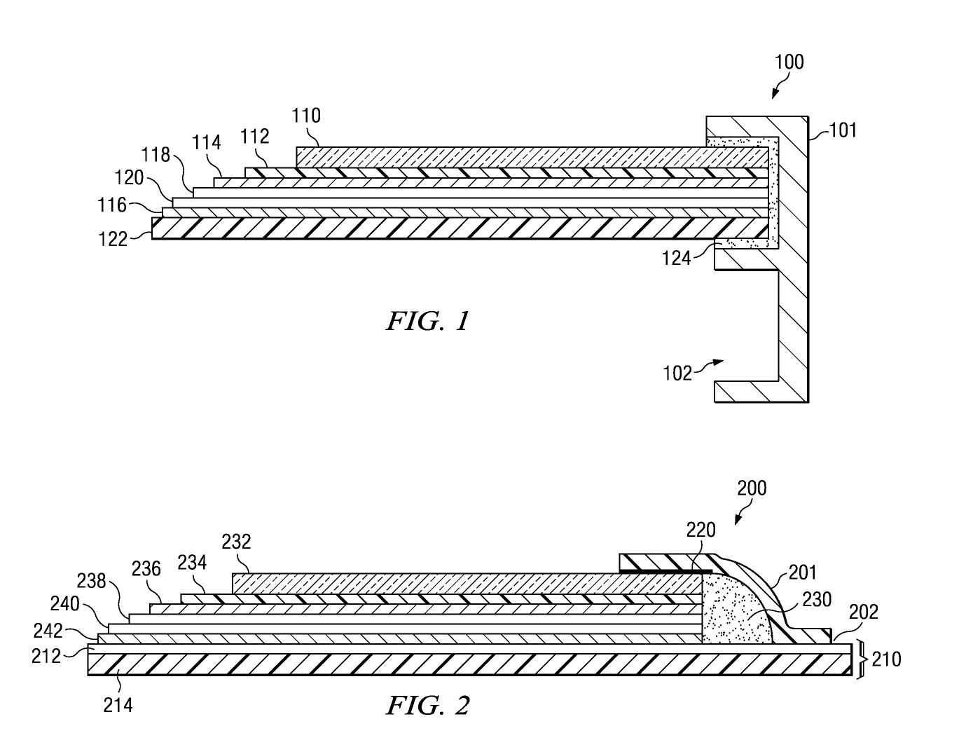

FIG. 1 is a drawing illustrating a partial side cross-sectional view of the construction of a conventional photovoltaic module 100 for a generic silicon type solar cell. A rack to hold the module 100 includes a metal frame 101 for both protection of the edge of the photovoltaic module 100 and as a means of mounting the cell to the structure. More specifically, the slot 102 of the metal frame 101 provides a means for mounting the photovoltaic module 100, and the metal frame 101 provides mechanical protection for the edge of various layers of the photovoltaic module 100. A glass superstrate 110 is the top layer of the photovoltaic module 100, which necessarily results in the module 100 being a rigid module 100. Such rigid modules 100 use racks, as mentioned above, to seal the edges of the module 100 as well as to affix the modules 100 to the structure. Unfortunately, such racks used with rigid systems add complexity and cost to the manufacturing and installation process.

Also as illustrated, an anti-reflection film 112 may be layered beneath the glass superstrate. Electrode contacts 114 and 116 surround n-type silicon layer 118 and p-type silicon layer 120. The n-type silicon layer 118 is at least partially transparent. Alternatively, the p-type silicon layer 120 may be on top of the n-type silicon layer 118, in which case the p-type silicon layer 120 is at least partially transparent. The backside of the photovoltaic module 100 is comprised of a protective film 122, which provides a very low permeability barrier to moisture ingress to prevent long term damage to the cell structure. The protective film is typically a polyvinyl fluoride material, such as Tedlar®. A layer of caulk 124 is used between the photovoltaic cell and the metal frame 101.

To overcome some of the problems associated with such conventional manufacturing techniques, a photovoltaic module constructed according to the disclosed principles provides for the use of a polymer film, such as a fluorinated vinyl polymer film, as the bottom layer of the photovoltaic cell. Such a fluorinated vinyl polymer film may comprise, for example, polyvinyl fluoride (PVF) or polyvinylidene fluoride (PVDF); however, any film providing a moisture barrier to the bottom surface of the photovoltaic cell may be employed. The moisture barrier polymer film is laminated to the top surface of a thermoplastic roofing membrane, such as a thermoplastic olefin (TPO) membrane. The resulting membrane can then be used as the backsheet for sealing the photovoltaic cells/modules onto a similar TPO membrane previously applied to the roof or other structure.

FIG. 2 is a partial side cross-sectional view of the construction of a photovoltaic module 200 for a generic silicon type solar cell in accordance with the present disclosure. The photovoltaic module 200 in FIG. 2 is a generic silicon-based cell, but could be implemented with any other type of active layer in a photovoltaic panel. A superstrate 232 is the top layer of the photovoltaic module 200 and an anti-reflection film 234 is layered beneath the superstrate 232. The superstrate 232 may be a glass sheet. The superstrate 232 may also be a flexible material. The superstrate 232 is transparent and in an embodiment, is a transparent heat-weldable thermoplastic sheet. Electrode contacts 236 and 242 surround n-type silicon layer 238 and p-type silicon layer 240. In an embodiment, the n-type silicon layer 238 is at least partially transparent. In another embodiment, the p-type silicon layer 240 may be on top of the n-type silicon layer 238, in which case the p-type silicon layer 240 is at least partially transparent. Although a hard, glass solar cell is illustrated, a flexible cell may also be incorporated with the disclosed principles.

Since about 1975, thermoplastic membranes have been advantageously used as a single-ply roofing or building membrane. Since about 1995, such membranes have been increasingly produced using thermoplastic olefin (TPO) film. The TPO membrane is typically applied in the field using a one layer membrane material (either homogeneous or composite) rather than multiple layers built-up. These membranes have been advantageously used on low-slope roofing structure, as well as other applications. The TPO membrane can comprise one or more layers, have a top and bottom surface, and may include a reinforcing scrim or stabilizing material. The scrim is typically of a woven, nonwoven, or knitted fabric composed of continuous strands of material used for reinforcing or strengthening membranes. Other materials from which the membrane may be formed include but are not limited to polyvinyl chloride (PVC), chlorosulfonated polyethylene (CSPE or CSM), chlorinated polyethylene (CPE), and ethylene propylene diene terpolymer (EPDM).

In an exemplary embodiment of the disclosed principles, the fluoropolymer substrate 122 typically found on photovoltaic modules has been replaced with a heat-weldable thermoplastic membrane 210. In an exemplary embodiment, the heat-weldable thermoplastic membrane 210 comprises TPO. The heat-weldable thermoplastic membrane 210 may comprise a thin cap layer of a fluoropolymer film 212 laminated to a base thermoplastic roofing membrane 214. The fluoropolymer film 212 could be comprised of polyvinylidene fluoride and could be laminated to the thermoplastic membrane 214 via the use of one ore more tie layers, whether fluoropolymer based or from a different compound. An example of such a combination is described in U.S. Published Patent Application 2008/0029210. The fluoropolymer film 212 may be thinner than a conventional backing film used on conventional photovoltaic modules, thereby reducing cost, while the heat-weldable thermoplastic membrane 214 may provide additional moisture barrier properties.

The heat-weldable thermoplastic protective membrane 210 on the underside of the photovoltaic module 200 may extend several inches or more beyond the edge of the cell. By forming the bottom surface of the photovoltaic module 200 or shingle from the same polymer membrane film 210 as the membrane laid on the roofing or other structure, and then by extending the backsheet some distance beyond the perimeter of the photovoltaic cell structure, the finished photovoltaic module 200 could then be heat-welded along the perimeter edge of the photovoltaic module onto a new or existing roofing membrane. In other embodiments, the underlying thermoplastic membrane includes an adhesive, such as hot melt butyl, disposed thereon. In such embodiments, the thermoplastic membrane having the photovoltaic module may be adhered to another roofing membrane placed on a roof deck, or even adhered to the deck directly. In such an embodiment, in the absence of a membrane laid on the roofing or other structure, the photovoltaic module 200 may serve as the roofing membrane.

In addition, the disclosed technique may replace the more complex mounting procedures and equipment conventionally used, such as the conventional approach illustrated in FIG. 1 and discussed above, when a flush mount is desired. The conventional metal frame around a photovoltaic cells may be eliminated and replaced with a frame of heat-weldable thermoplastic membrane 201 (or other thermoplastic polymer film) formed around the photovoltaic cell. In an embodiment, the frame 201 may be adhered to the superstrate 232 by the use of an adhesive 220 (e.g., a butyl rubber based material). Also, the heat-weldable thermoplastic frame 201 may extend down around the side edges of the layers comprising the photovoltaic cell, and may be heat-welded 202 to the base protective film 210 as illustrated. By encompassing the side edges of the photovoltaic cell layers, as well as being sealed to the outer perimeter of the top surface of the superstrate and being sealed to the base protective film, the frame not only provides a structure for holding the photovoltaic cells in place, but also provides for a moisture barrier for the side edges of the photovoltaic cells. As shown in FIG. 2, moisture-resistant caulking 230 may also be provided between the frame and the side edges of the photovoltaic cell layers for additional structural and sealing benefits. In the end, the disclosed approach would be especially advantageous for a sloped residential roof where aesthetics are important. Specifically, this approach would further lower the profile of the photovoltaic module for improved aesthetics and lower system cost.

In an advantageous embodiment, the photovoltaic module and thermoplastic membrane are heat-welded together in a factory and made into roll-stock. The roll-stock may be rolled onto a roof or other structure, increasing installation efficiency by being able to cover a substantial amount of decking by simply unrolling the disclosed product across the decking. In such embodiments, the photovoltaic modules may be flexible modules. However, since these flexible modules are affixed to the underlying thermoplastic membrane using heat-welding along the perimeter of the modules, the final roofing membrane will not suffer from the modules coming loose from the underlying membrane as typically results when “peel-and-stick” modules (i.e., modules adhered to a membrane merely by adhesive) are employed. More specifically, by affixing the solar modules to the underlying membrane in a factory setting, not only does the heat-welding process far out weight the longevity of merely adhesively attaching the modules to an underlying membrane, but the affixing of the modules in the factory settings allows complete control over the joining of the two components, something not available when the two are joined in the field.

In general, even conventional photovoltaic system that employ thin-film or other types of flexible solar modules or panels to employ the racks discussed above with respect to rigid solar cells. Thus, the use of flexible solar modules can already reduce the cost and complexity of manufacturing and installation. Moreover, however, the disclosed principles, in addition to employing flexible photovoltaic modules in many embodiments, also can provide further advantages over conventional flexible systems. For example, conventionally available flexible systems are manufactured using the peel-and-stick approach mentioned above. However, such an approach is still very time-consuming during installation. In addition, the adhesives employed on such conventional panels typically do not stand the tests of time, much less a 25 year or other long term warranty. Add to that the possibility that the installer inadvertently contaminates the adhesive backing during installation, and the longevity of the attachment of such conventional flexible modules may even be further reduced.

Still further, although the description herein pertains to the fusing of multiple individual photovoltaic cells to a heat-weldable thermoplastic membrane, it should be understood that the same principles may also be extended to the fusing of large arrays or sheets of flexible photovoltaic modules to such a thermoplastic membrane. In such embodiments, the frame 201 discussed above would simply be provided along the outer edge of the array sheet, rather than surrounding each single module. By sealing such an array to the underlying membrane by fusing a frame 201 around its perimeter, in addition to an adhesive that may be employed to stick the array to the membrane, the disclosed principles provide a more permanent means by which to affix the PV array to the membrane that would prevent the edges of the array from peeling away from the membrane over time.

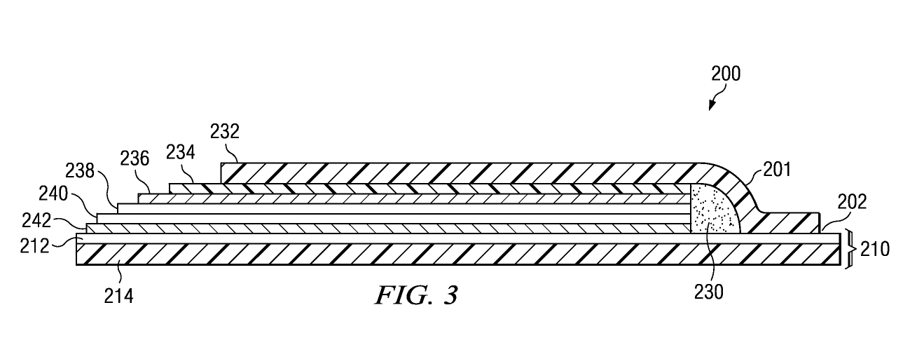

FIG. 3 is another embodiment of the photovoltaic module 200. In this embodiment, the superstrate 232 is actually a transparent, or even semi-transparent, heat-weldable thermoplastic membrane. Advantageously, the superstrate may be the same or a chemically similar heat-weldable thermoplastic material as the underlying thermoplastic membrane 210 and the frame 201. In such embodiments, since the superstrate 232 and frame 201 are substantially the same material, the superstrate 232 may be heat-welded to the frame 201, providing a moisture barrier around the entire photovoltaic module 200. Alternatively, the superstrate 232 may be formed to extend past the photovoltaic module layers around the superstrate's 232 perimeter. In such embodiments, since the superstrate would be a thermoplastic material, it may be made flexible such that the extended portions of the superstrate 232 extending past the photovoltaic modules on all its sides may be the frame 201. Thus, these extending portions providing the frame 201 may be heat-welded to the underlying membrane 210 around the perimeter of the photovoltaic module thereby providing the seal around the module and affixing it to the underlying membrane 210.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A photovoltaic roofing system, comprising:
a photovoltaic module, comprising:
an active layer, and
two electrodes,
a transparent superstrate, the transparent superstrate positioned on top of the photovoltaic module;
an underlying membrane comprising heat-weldable thermoplastic material positioned beneath the photovoltaic module; and
a frame comprised of the same heat-weldable thermoplastic material as the underlying membrane and located on a perimeter of the superstrate and the photovoltaic module, the frame heat-welded to the underlying membrane around the perimeter of the photovoltaic module.

2. A photovoltaic roofing system according to claim 1, further comprising a fluoropolymer film, the fluoropolymer film laminated to the underlying membrane and under the photovoltaic module.

3. A photovoltaic roofing system according to claim 2, wherein the fluoropolymer film comprises polyvinylidene fluoride and is laminated to the underlying membrane using a tie layer.

4. A photovoltaic roofing system according to claim 1, wherein the transparent superstrate is a glass sheet.

5. A photovoltaic roofing system according to claim 1, wherein a surface of the underlying membrane opposite the photovoltaic module includes an adhesive thereon.

6. A photovoltaic roofing system according to claim 5, wherein the adhesive is hot melt butyl.

7. A photovoltaic roofing system according to claim 1, wherein the perimeter of the underlying membrane is heat-welded to a thermoplastic roofing membrane.

8. A photovoltaic roofing system according to claim 1, further comprising an anti-reflective film positioned between the transparent superstrate and the photovoltaic module.

9. A photovoltaic roofing system according to claim 1, wherein the heat-weldable thermoplastic material is thermoplastic olefin.

10. A photovoltaic roofing system according to claim 1, wherein the frame is adhered to an exterior surface of the transparent superstrate with an adhesive proximate its perimeter.

11. A photovoltaic roofing system according to claim 1, wherein the transparent superstrate comprises a flexible thermoplastic material heat-weldable to the thermoplastic material comprising the underlying membrane, and wherein the perimeter of the flexible superstrate comprises the frame and is heat-welded to the underlying membrane.

12. A photovoltaic roofing system according to claim 1, further comprising moisture-resistant caulking, the caulking located on the edges of the photovoltaic module and the transparent superstrate, and within the frame to seal the edges of the photovoltaic module and the transparent superstrate.

13. A method of manufacturing a photovoltaic roofing membrane, the method comprising:
constructing a photovoltaic module by:
providing an active layer, and
providing two electrodes;
locating a transparent superstrate on top of the photovoltaic module;
positioning an underlying membrane comprising heat-weldable thermoplastic material beneath the photovoltaic module;
providing a frame comprised of the same heat-weldable thermoplastic material as the underlying membrane on a perimeter of the transparent superstrate and the photovoltaic module; and
heat-welding the frame to the underlying membrane around the perimeter of the photovoltaic module.

14. A method according to claim 13, further comprising laminating a fluoropolymer film to the underlying membrane and under the photovoltaic module.

15. A method according to claim 14, further comprising laminating the fluoropolymer film to the underlying membrane using a tie layer.

16. A method according to claim 13, further comprising providing an adhesive on a surface of the underlying membrane opposite the photovoltaic module.

17. A method according to claim 16, wherein the adhesive is hot melt butyl.

18. A method according to claim 13, further comprising heat-welding the perimeter of the underlying membrane to a thermoplastic roofing membrane.

19. A method according to claim 13, further comprising positioning an anti-reflective film between the transparent superstrate and the photovoltaic module.

20. A method according to claim 13, wherein the heat-weldable thermoplastic material is thermoplastic olefin.

21. A method according to claim 13, further comprising adhering the frame to an exterior surface of the transparent superstrate proximate its perimeter with an adhesive.

22. A method according to claim 13, wherein the transparent superstrate comprises a flexible thermoplastic material heat-weldable to the thermoplastic material comprising the underlying membrane, and the perimeter of the flexible superstrate comprises the frame heat-welded to the underlying membrane.

23. A method according to claim 13, further comprising providing moisture-resistant caulking on the edges of the photovoltaic module and the transparent superstrate, and within the frame to seal the edges of the photovoltaic module and the transparent superstrate.

24. A photovoltaic roofing system, comprising:
a photovoltaic module, comprising:
an active layer, and
two electrodes;
a transparent superstrate positioned on top of the photovoltaic module;
an underlying membrane comprising heat-weldable thermoplastic material and having a fluoropolymer film laminated thereon, the photovoltaic module located on the fluoropolymer film;
a frame comprised of the same heat-weldable thermoplastic material as the underlying membrane and located on a perimeter of the transparent superstrate and the photovoltaic module, the frame heat-welded to the fluoropolymer film and underlying membrane around the perimeter of the photovoltaic module; and
a moisture sealing material located on the edges of the photovoltaic module and the transparent superstrate, and within the frame to seal the edges of the photovoltaic module and the superstrate.

25. A photovoltaic roofing system according to claim 24, wherein the underlying membrane extends beyond the edge of the photovoltaic module and wherein the perimeter of the underlying membrane is heat-welded to a thermoplastic roofing membrane;

26. A photovoltaic roofing system according to claim 24, wherein the transparent superstrate comprises a flexible thermoplastic material heat-weldable to the thermoplastic material comprising the underlying membrane, and the perimeter of the flexible superstrate comprises the frame heat-welded to the underlying membrane.

27. A photovoltaic roofing system according to claim 24, wherein the heat-weldable thermoplastic material is thermoplastic olefin.

28. A photovoltaic roofing system according to claim 24, further comprising an anti-reflective film positioned between the transparent superstrate and the photovoltaic module.

29. A photovoltaic roofing system according to claim 24, wherein the frame is adhered to an exterior surface of the transparent superstrate proximate its perimeter with an adhesive.

30. A photovoltaic roofing system according to claim 24, wherein a surface of the underlying membrane opposite the photovoltaic module includes an adhesive thereon.
